(19) United States
(12) Patent Application Publication
(10) Pub. No.: US 2020/0044631 A1
(43) Pub. Date: Feb. 6, 2020

(54) D FLIP-FLOPS WITH LOW CLOCK DISSIPATION POWER

(71) Applicant: SAMSUNG ELECTRONICS CO., LTD., Suwon-si (KR)

(72) Inventors: Shyam AGARWAL, Kaggadasapura (IN); Sandeep B V, Bangalore (IN); Sheetal Y KOCHREKAR, Karwar (IN); Abhishek GHOSH, Bangalore (IN); Parvinder Kumar RANA, Bangalore (IN); Rohit BISHT, Bangalore (IN)

(73) Assignee: SAMSUNG ELECTRONICS CO., LTD., Suwon-si (KR)

(21) Appl. No.: 16/152,931

(22) Filed: Oct. 5, 2018

(30) Foreign Application Priority Data
Aug. 1, 2018 (IN) 201841029006

(51) Int. Cl. H03K 3/3562; H03K 3/012

(52) U.S. Cl. CPC H03K 3/35625; H03K 3/012

(57) ABSTRACT

A D flip-flop includes a master block configured to latch an input value of D at one of rising edge and a falling edge of a clock signal, based on the clock signal, the input value of D, and an inverted value of D, and a slave block configured to propagate the input value of D at another one of the falling edge and the rising edge of the clock signal, based on the clock signal.

### BACKGROUND

### 1. Field

Apparatuses consistent with embodiments relate to System on a Chip (SOC) circuits, and more particularly to D flip-flops with low clock dissipation power.

### 2. Description of Related Art

D flip-flops are a basic unit of a sequential or storage standard cell circuit. Due to their size, the D flip-flops can be one of the influential elements in terms of System on a Chip (SoC) area, power and performance. For example, all forms of sequential cells can be derived from the D flip-flop. Sequential cells can occupy a significant part of total standard cell area in a SoC. A sequential cell including a clock network may contribute to about half of total power consumed by the SoC. Any cell level impact in the sequential cell can directly impact power consumption of the SoC.

The components of a D flip-flop circuit can include technologies such as a Fin Field-Effect Transistor (FINFET) (14 nm, 10 nm, 8 nm, and so on), which have a high dynamic power dissipation and a delay due to a high gate capacitance. In a FINFET, SoC dynamic power can be more than ten to hundred times than that of leakage power. If the size of the sequential cell is reduced for minimizing dynamic power consumption, then the delay of the sequential cell may increase. This can minimize efficiency of the sequential cell.

FIG. 1 is a circuit diagram illustrating a D flip-flop circuit. As depicted in FIG. 1, a clock signal CK is fed to a buffer block 101 consisting of two Complementary Metal-Oxide-Semiconductor (CMOS) inverters (MOSFET pair P15 and N15 and MOSFET pair P16 and N16). The inverted version of the clock signal can be referred to as NCLK. The inverted version of NCLK is a DCLK signal, whose polarity is similar to the clock signal. The NCLK and DCLK signals can be used as clock signals in the D flip-flop circuit, as annotated in FIG. 1.

The D flip-flop circuit has a master-slave topology, which allows the value of D to propagate through a master block 102 and a slave block 103, within a rising and a falling transition of the clock signal. The master block 102 allows the value of D to propagate to the input of the slave block when the clock signal is reset. Similarly, the slave block 103 allows the value of D at its input to propagate to Q (output of the D flip-flop circuit) when the clock signal is set. The master block 102 and the slave block 103 can retain the values at the input through feedback channels in the respective blocks.

Consider that the value of D is ‘1’ and the clock signal is reset, the NCLK will be set and the DCLK will be reset. At the input of the master block 102, the MOSFET stack P1, P2, N1, N2 is active and would pass on the value of D inside the master latch. The value of D can be propagated to the inverter (MOSFET pair P21 and N21), having a polarity, which is inverted to that of D. The polarity of the output of the inverter will be same as that of D. The slave block 103 will be off as the MOSFET pair P7 and N7 will be off. The feedback unit (MOSFET pair P9 and N10) in the master block 102 will be off. The value of D will be retained through the feedback unit when the clock signal is set.

When the clock signal is set, the NCLK will be reset and the DCLK will be set. At the input of the slave block 103, the MOSFET stack P6, P7, N7, N8 is active and will allow the latched in value of D (by the master) to be propagated into the slave. The value of D can be propagated to the inverter (MOSFET pair P14 and N14), having a polarity, which is inverted to that of D. The polarity of the output of the inverter will be same as that of D. The value of D is therefore passed to Q (output of the D flip-flop circuit). The master block 102 will be off as the MOSFET pair P2 and N1 will be off. The feedback unit (MOSFET pair P18 and N19) in the slave block 103 will be off and the value of D is passed to Q (output of the D flip-flop circuit). When the clock signal is reset, the value of Q will be retained through the feedback unit.

The power consumption of the D flip-flop circuit can be high due to generating the NCLK and DCLK signals using two explicit CLK inverters, MOSFET pair P15 and N15, and MOSFET pair P16 and N16 (buffer block 101). The gate loading can be high for clock signals. There can be issues of robustness due to dependency of two clock phase signals, the NCLK and the DCLK.

FIG. 2 is a circuit diagram illustrating another D flip-flop circuit. The D flip-flop circuit herein utilizes Transmission Gates (TGs), as annotated in FIG. 2. The power consumption of the D flip-flop circuit can be high due to generating the NCLK and DCLK signals using two explicit CLK inverters. The gate loading can be high for clock signals. There can be issues of robustness due to dependency of two clock phase signals, the NCLK and the DCLK.

### SUMMARY

According to embodiments, a D flip-flop includes a master block configured to latch an input value of D at one of rising edge and a falling edge of a clock signal, based on the clock signal, the input value of D, and an inverted value of D, and a slave block configured to propagate the input value of D at another one of the falling edge and the rising edge of the clock signal, based on the clock signal.

According to embodiments, a D flip-flop includes a master block configured to latch an input value of D at one of a rising edge and a falling edge of a clock signal, based on an inverted version of the clock signal, the input value of D, and an inverted value of D, and a slave block configured to propagate the input value of D at another one of the falling edge and the rising edge of the clock signal, based on the clock signal and the inverted version of the clock signal.

According to embodiments, a D flip-flop includes a master block configured to latch an input value of D at another one of a rising edge and a falling edge of a clock signal, based on an inverted version of the clock signal, the input value of D, and an inverted value of D, and a slave block configured to propagate the input value of D at another one of the falling edge and the rising edge of the clock signal, based on the inverted version of the clock signal.

### BRIEF DESCRIPTION OF DRAWINGS

FIG. 1 is a circuit diagram of a D flip-flop circuit.

FIG. 2 is a circuit diagram of another D flip-flop circuit.

FIG. 3 is a circuit diagram of a first D flip-flop circuit, according to embodiments.

FIG. 4 is a circuit diagram of a second D flip-flop circuit, according to embodiments.

FIG. 5 is a circuit diagram of a third D flip-flop circuit, according to embodiments.

FIGS. 6A and 6B are diagrams of layout areas of the first D flip-flop circuit of FIG. 3 and the second D flip-flop circuit of FIG. 4, respectively.

### DETAILED DESCRIPTION OF EMBODIMENTS

Embodiments provide D flip-flops with a low clock dissipation power.

Embodiments also provide D flip-flops with a low voltage operability at an optimal area for usage in high performance standard cell libraries.

Embodiments further provide D flip-flops that are robust against problems such as data retention, data contention, write-back, internal-hold failure, and so on.

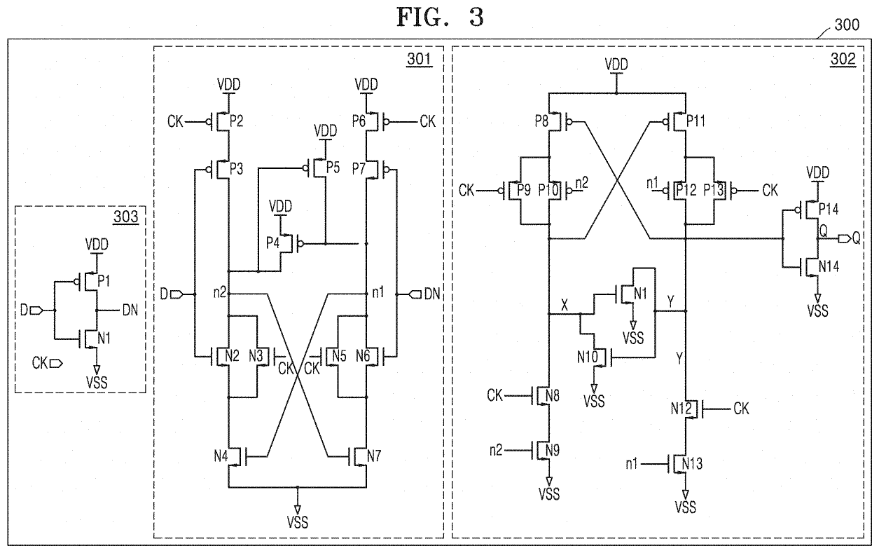

FIG. 3 is a circuit diagram of a first D flip-flop circuit 300, according to embodiments. The first D flip-flop circuit 300 operates in one of the phases of the clock (CK) signal. The first D flip-flop circuit 300 includes a master block 301 and a slave block 302. The purpose of the master block 301 is to hold the input value of D when the CK is reset, and the purpose of the slave block 302 is to pass the value of D at the rising edge of the CK signal. The master block 301 allows the value of D to propagate to the input of the slave block 302 when the CK signal is reset. Similarly, the slave block 302 allows the value of D, at its input, to propagate to Q (output of the first D flip-flop circuit 300) when the CK signal is set. The master block 301 and the slave block 302 include a network of transistors in CMOS and TG configurations for holding and passing the value of D at the appropriate phase of the CK signal.

As depicted in FIG. 3, the first D flip-flop circuit 300 operates in a single phase of the CK signal. The value of D can be fed to an inverter 303 to generate DN, whose polarity is opposite of D. The master block 301 and the slave block 302 can be connected through nodes n1 and n2. The CK signal and values of D and DN can be fed as inputs to the master block 301, and the CK and values at the nodes n1 and n2 can be fed as inputs to the slave block 302. For simplicity, the connections between the master block 301 and the slave block 302 are not depicted.

In an example, consider that the value of D is ‘0’ (reset) and the CK signal is reset (0). The value of DN will be ‘1’ by the operation of the inverter 303 (P1 and N1). At the input of the master block 301, P2 and P3 will be on while N2 and N3 will be off. As such, the voltage at node n2 will be pulled to voltage VDD (a first voltage source). The value at node n2 will be ‘1’. As DN is ‘1’ and CK is ‘0’, P7 and N5 will be off and N6 and P6 will be on. As the state of node n2 is fed as input to N7, the N7 will be on. Therefore, the voltage at node n1 will be pulled to voltage VSS. The value at node n1 will be ‘0’, and N4 will be off. The master block 301 retains or latches the value of D as long as the CK signal is reset. In the figures herein, ‘P’ may refer to a P-channel Metal Oxide Semiconductor (PMOS) transistor, and ‘N’ may refer to an N-channel Metal Oxide Semiconductor (NMOS) transistor.

When the CK is set, the slave block 302 can propagate the value of D to Q (output of the first D flip-flop circuit 300). As values of the CK signal and the n2 are ‘1’; P9, P10 and P13 will be off, and N8, N9 and N12 will be on. As such, the voltage at node X will be pulled to voltage VSS. The value at node X will be ‘0’. As the values of node X and at node n1 are ‘0’; P11 and P12 will be on, and N13 will be off. As such, the voltage at node Y will be pulled to voltage VDD. The value at node Y will be ‘1’, and P8 will be off. The value at node Y can be fed to an inverter (P14 and N14), and the output of the inverter (Q) will be ‘0’. Thus, the value of D is propagated to the output of the slave block 302 at the rising edge of the CK signal.

The master block 301 includes transistors P4 and P5, and the slave block 302 includes transistors N10 and N11, which increase stability of the respective blocks. If there is a skew or process variation at the input of the master block 301 and the slave block 302, the transistors can ensure that the voltages at nodes n1 and n2 are of opposite polarity and the voltages at nodes X and Y are of opposite polarity.

The power consumption of the first D flip-flop circuit 300 can be significantly reduced by regulating the clock related operations of the first D flip-flop circuit 300, exclusively with the CK signal. The need for generating the NCLK and DCLK signals using a clock buffer is done away with. The gate loading can be high for clock signals. There may not be clock power dissipation at the same data cycle due to absence of clock buffer in the first D flip-flop circuit 300. The first D flip-flop circuit 300 can be robust due to absence of dependence on both phases of the CK signal. The first D flip-flop circuit 300 can operate at sub-threshold voltages.

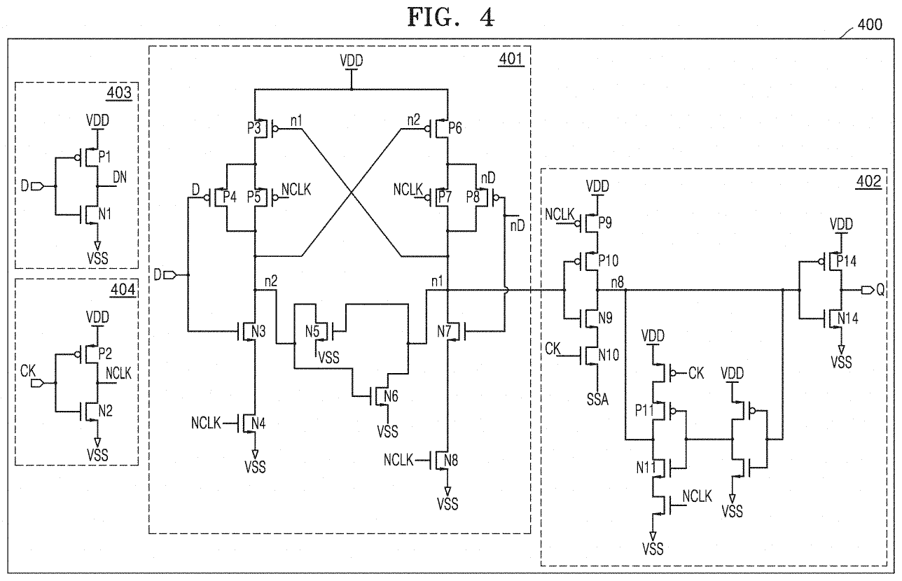

FIG. 4 is a circuit diagram of a second D flip-flop circuit 400, according to embodiments. The second D flip-flop circuit 400 includes a master block 401 and a slave block 402. The purpose of the master block 401 is to hold the value of D when the CK is reset, and the purpose of the slave block 402 is to pass the value of D at the rising edge of the CK signal. The master block 401 allows the value of D to propagate to the input of the slave block 402 when the CK signal is reset. Similarly, the slave block 402 allows the value of D, at its input, to propagate to Q (output of the second D flip-flop circuit 400) when the CK signal is set. The master block 401 and the slave block 402 include a network of transistors in CMOS and TG configurations for holding and passing the value of D at the appropriate phase of the CK signal.

As depicted in FIG. 4, the second D flip-flop circuit 400 includes two inverters to obtain opposite polarities of D and the CK signal. The value of D can be fed to an inverter 403 to generate nD, whose polarity is opposite to that of D. The value of the CK signal can be fed to an inverter 404 to generate NCLK, whose polarity is opposite to that of the CK signal. The master block 401 and the slave block 402 can be connected through node n1. The NCLK signal and values of D and nD can be fed as inputs to the master block 401, and the NCLK, the CK, and value at the node n1 can be fed as inputs to the slave block 402.

In an example, consider that the value of D is ‘0’ (reset) and the CK signal is reset (0). The value of nD will be ‘1’ by the operation of the inverter 403 (P1 and N1). The value of the NCLK will be ‘1’ by the operation of the inverter 404 (P2 and N2). At the input of the master block 401, P3, P4 and N4 will be on, while N3 and P5 will be off. As such, the voltage at node n2 will be pulled to voltage VDD. The value at node n2 will be ‘1’. As nD and NCLK are ‘1’, P7 and P8 will be off. As the value at node n2 is ‘1’, P6 will also be off. As nD and NCLK are ‘1’, N7 and N8 will be on. Therefore, the voltage at node n1 will be pulled to voltage VSS. The value at node n1 will be ‘0’. The master block 401 retains the value of D as long as the CK signal is reset.

When the CK is set (1), the slave block 402 can propagate the value of D to Q (output of the second D flip-flop circuit 400). As value of the CK signal is ‘1’, and NCLK and the value at node n1 are ‘0’; N9 will be off, and P9, P10 and N10 will be on. As such, the voltage at node n8 will be pulled to voltage VDD. The value at node n8 will be ‘1’. The value at node n8 can be fed to an inverter (P14 and N14), and the output of the inverter (Q) will be ‘0’. The feedback unit (MOSFET pair P11 and N11) in the slave block 402 will be off and the value of D is passed to Q (output of the D flip-flop circuit). Thus, the value of D is propagated to the output of the slave block 402 at the rising edge of the CK signal.

The master block 401 includes transistors N5 and N6, which increase stability of the master block 401. If there is a skew or process variation at the input of the master block 401 the transistors N5 and N6 can ensure that the voltages at nodes n1 and n2 are of opposite polarity.

The power consumption of the second D flip-flop circuit 400 can be significantly reduced by regulating the clock related operations, of the second D flip-flop circuit 400, using the CK and the NCLK signal. The second D flip-flop circuit 400 does not include a clock buffer, which is the primary contributor of clock power and SoC power. The gate loading can be low for clock signals. The propagation delay of the second D flip-flop circuit 400 can be lower. There may not be clock power dissipation at the same data cycle due to absence of clock buffer in the second D flip-flop circuit 400. The second D flip-flop circuit 400 can be robust due to absence of dependence on both phases of the CK signal. The second D flip-flop circuit 400 can operate at sub-threshold voltages.

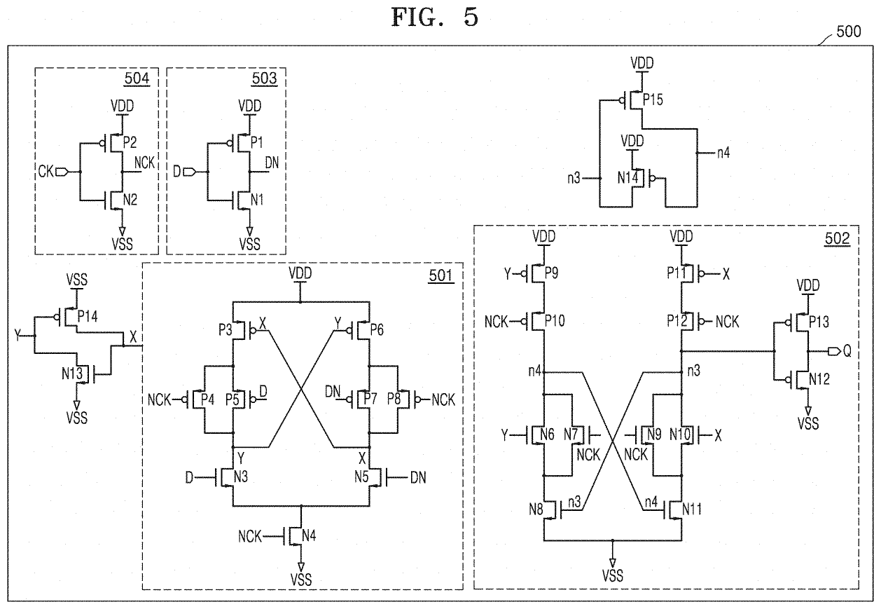

FIG. 5 is a circuit diagram of a third D flip-flop circuit 500, according to embodiments. The third D flip-flop circuit 500 includes a master block 501 and a slave block 502. The purpose of the master block 501 is to hold the value of D when the CK is reset, and the purpose of the slave block 502 is to pass the value of D at the rising edge of the CK signal. The master block 501 allows the value of D to propagate to the input of the slave block 502 when the CK signal is reset. Similarly, the slave block 502 allows the value of D, at its input, to propagate to Q (output of the third D flip-flop circuit 500) when the CK signal is set. The master block 501 and the slave block 502 include a network of transistors in CMOS and TG configurations for holding and passing the value of D at the appropriate phase of the CK signal.

As depicted in FIG. 5, the third D flip-flop circuit 500 includes two inverters to obtain opposite polarities of D and the CK signal. The value of D can be fed to an inverter 503 to generate DN, whose polarity is opposite to that of D. The value of the CK signal can be fed to an inverter 504 to generate NCK, whose polarity is opposite to that of the CK signal. The master block 501 and the slave block 502 can be connected through the nodes X and Y. The NCK signal and values of D and DN can be fed as inputs to the master block 501, and the NCK and values at the nodes X and Y can be fed as inputs to the slave block 502.

In an example, consider that the value of D is ‘0’ (reset) and the CK signal is reset (0). The value of DN will be ‘1’ by the operation of the inverter 503 (P1 and N1). The value of the NCK will be ‘1’ by the operation of the inverter 504 (P2 and N2). At the input of the master block 501, N4, N5 and P5 will be on, while P4 and N3 will be off. As such, the voltage at node X will be pulled to voltage VSS. The value at node X will be ‘0’. As DN and NCK are ‘1’, P7 and P8 will be off. As the value at node X is ‘0’, P3 will also be on. As P5 will be on, the voltage at node Y will be pulled to voltage VDD. The value at node Y will be ‘1’. The master block 501 retains the value of D as long as the CK signal is reset.

When the CK is set (1), the slave block 502 can propagate the value of D to Q (output of the third D flip-flop circuit 500). As value of the CK signal is ‘1’, NCK is ‘0’, the value at node X is ‘0’ and the value at node Y is ‘1’; P9 will be off, and P10, P11 and P12 will be on. As such, the voltage at node n3 will be pulled to voltage VDD. The value at node n3 will be ‘1’. As the values at node Y and at node n3 are ‘1’ and NCK and the value at node X are ‘0’, N6 and N8 will be on, and P9 will be off. As such, the voltage at node n4 will be pulled to voltage VSS. The value at node n4 will be ‘0’, and N11 will be off. The value at node n3 can be fed to an inverter (P13 and N12), and the output of the inverter (Q) will be ‘0’. Thus, the value of D is propagated to the output of the slave block 502 at the rising edge of the CK signal.

The master block 501 includes transistors P14 and N13, which increase stability of the master block 501. As such the voltages at nodes X and Y are of opposite polarity. The slave block 502 includes transistors P15 and N14, which increase stability of the slave block 502. As such the voltages at nodes n3 and n4 are of opposite polarity. If there is a skew or process variation at the inputs of the master block 501 and the slave block 502, the transistors can ensure that the voltages at nodes X and Y are of opposite polarity and the voltages at nodes n3 and n4 are of opposite polarity.

The power consumption of the third D flip-flop circuit 500 can be significantly reduced by regulating the clock related operations of the third D flip-flop circuit 500, using the CK and the NCK signal. The third D flip-flop circuit 500 does not include a clock buffer, which is the primary contributor of clock power and SoC power. The gate loading can be low for clock signals. There may not be clock power dissipation at the same data cycle due to absence of clock buffer in the third D flip-flop circuit 500. The third D flip-flop circuit 500 can be robust due to absence of dependence on both phases of the CK signal. The third D flip-flop circuit 500 can operate at sub-threshold voltages.

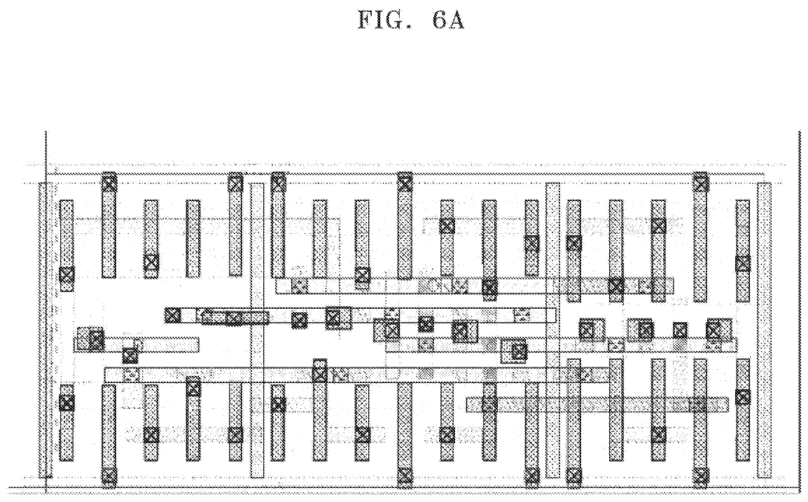

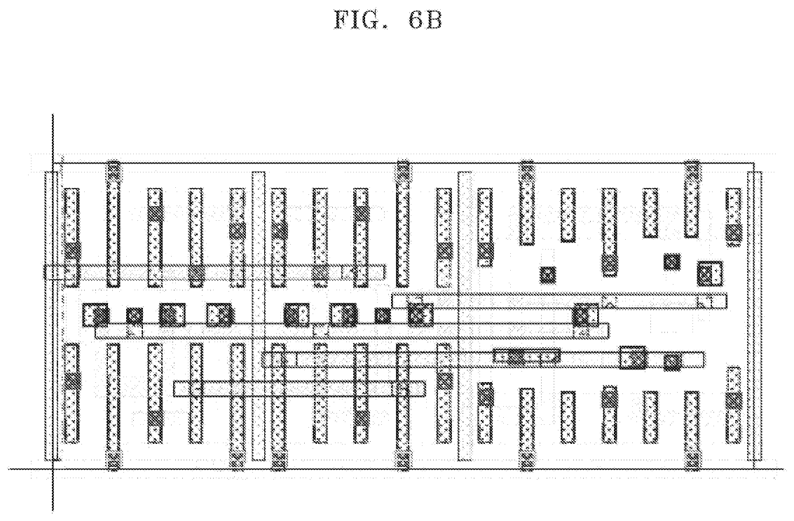

FIGS. 6A and 6B are diagrams of layout areas of the first D flip-flop circuit 300 of FIG. 3 and the second D flip-flop circuit 400 of FIG. 4, respectively. The number of grids in the both the first D flip-flop circuit 300 and the second D flip-flop circuit 400 is 17.

The D flip-flop circuits can operate in a single phase of the clock signal. This increases the robustness of the D flip-flop circuits. The lack of necessity of generating two phases of the clock signal can minimize power consumption of the D flip-flop circuits. The D flip-flop circuits can be sensitive to low voltages, such as sub-threshold voltages. The robustness of the D flip-flop circuits can be inferred from the following table.

TABLE 1

| | VDD | 0.4 | 0.435 | 0.45 | 0.5 | 0.6 |
|---|---|---|---|---|---|---|
| Existing D Flip- | FS | 32 | 17 | 8 | 0 | 0 |
| Flop circuit | SF | 2 | 1 | 1 | 0 | 0 |
| | TT | 5 | 0 | 0 | 0 | 0 |
| First D flip- | FS | 6 | 2 | 0 | 0 | 0 |
| flop circuit | SF | 1 | 0 | 0 | 0 | 0 |
| | TT | 2 | 2 | 0 | 0 | 0 |
| Second D flip- | FS | 4 | 3 | 0 | 0 | 0 |
| flop circuit | SF | 1 | 0 | 0 | 0 | 0 |
| | TT | 3 | 2 | 0 | 0 | 0 |

Table 1 depicts number of instances in which inputs at the master block and/or the slave block of the respective D flip-flop circuits have been misinterpreted, when drain voltage VDD (of the transistors in the respective D flip-flop circuits) is in the sub-threshold range (0.4V-0.6V). The misinterpretation (‘0’ for ‘1’ or ‘1’ for ‘0’) can likely lead to the inability of the D flip-flop circuit to propagate the value of D from input of the D flip flop circuit to the output of the D flip flop circuit. Minimum misinterpretations (ideally 0) indicate efficient robustness criteria. Each of the D flip-flop circuits, i.e., existing D flip flop circuit, the first D flip-flop circuit 300 and the second D flip-flop circuit 400), can be tested or evaluated at three process corners, e.g., Fast-Slow (FS), Slow-Fast (SF) and Typical-Typical (TT), which refer to NMOS and PMOS strength in silicon.

As depicted in table 1, for a drain voltage of 0.5V, the number of misinterpretations of the existing D flip flop circuit is equal to that of the first D flip-flop circuit 300 and the second D flip-flop circuit 400. When the drain voltage is dropped below that 0.5V, the likelihood of increase in the number of misinterpretations start to increase in the existing D flip flop circuit, in comparison with the first D flip-flop circuit 300 and the second D flip-flop circuit 400. The effect is compounded when the drain voltage is further lowered to 0.4V.

Single-clock phase operability of the D flip-flop circuits allows minimizing the size of the clock inverter, which in turn allows minimizing input capacitance of clock pin (CLK), and SoC level latency and power. The D flip-flop circuits can have a balanced rise and fall delay.

TABLE 2

| | Delay | CLK Power | Area | SoC Power |
|---|---|---|---|---|
| CELL | Reduction | Reduction | (No. of grids) | Reduction |
| First D flip- | −4% | 49% | 17 | 15% |
| flop circuit | | | | |
| Second D flip- | 2% | 26% | 17 | 8% |
| flop circuit | | | | |
| Third D flip- | −4% | 35% | 19 | 10% |
| flop circuit | | | | |

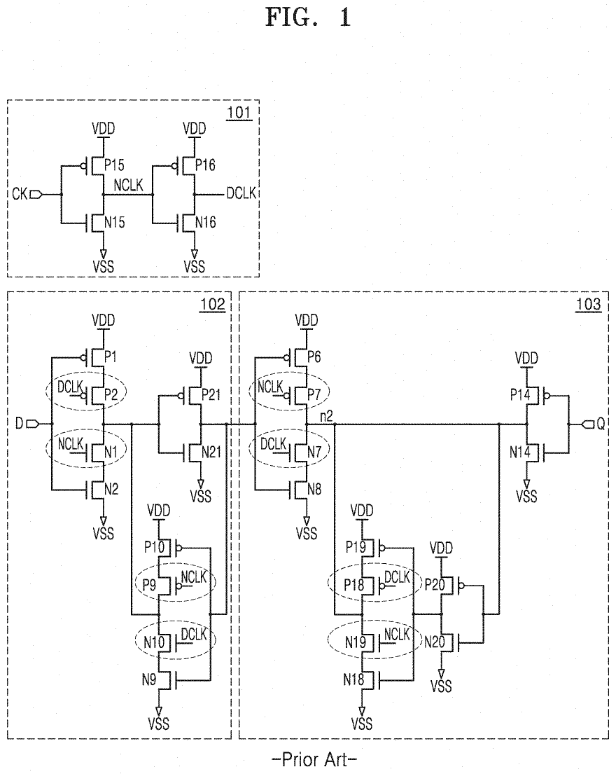

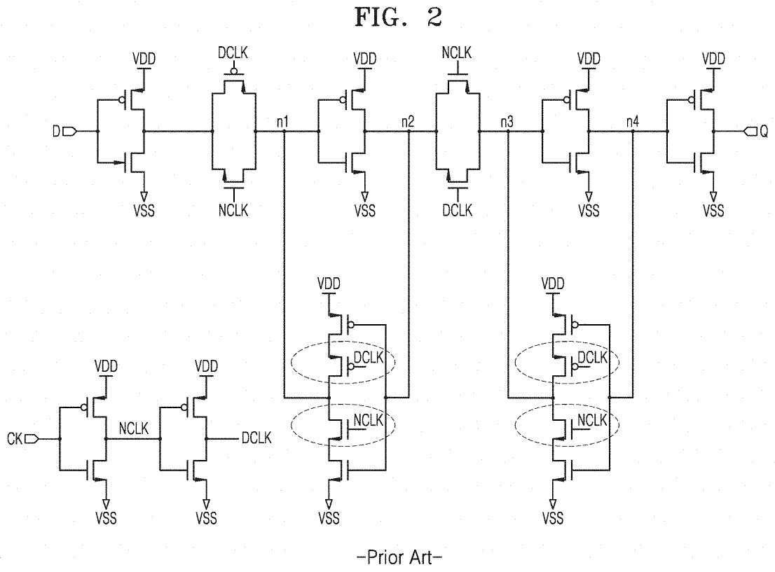

Table 2 depicts a performance comparison between first, second and third D flip-flop circuits, as depicted in FIGS. 3, 4 and 5 respectively. The performance statistics of the D flip-flop circuits can be obtained by comparing the parameters of table 2 with the existing sequential cells (described in FIG. 1 and FIG. 2). As depicted in table 2, the clock power of the D flip-flop circuits has significantly reduced at similar or minimized delay, in comparison with existing sequential cells.

The usage of cross coupled poly pattern can be prevented in the D flip-flop circuits. This can be an advantage as the cross coupled poly pattern (SIC-XC) can have a higher manufacturing cost and more can be prone to process variations. The design used in the D flip-flop circuits can be extended to other sequential cells. The D flip-flop circuits can be designed using FINFET or deep submicron technologies.

The embodiments disclosed herein can be implemented through at least one software program running on at least one hardware device and performing network management functions to control the network elements. The network elements shown in FIGS. 3, 4, and 5, include blocks, which can be a hardware device, or a combination of hardware device and software module.

The embodiments disclosed herein describe D flip-flops with low clock dissipation power. Therefore, it is understood that the scope of the protection is extended to such a program and in addition to a computer readable storage medium having a message therein, such a computer readable storage medium containing program code for implementation of one or more steps of the method, when the program runs on a server or mobile device or any suitable programmable device. The method is implemented through or together with a software program written in e.g., Very high speed integrated circuit Hardware Description Language (VHDL) or another programming language, or implemented by one or more VHDL or several software modules being executed on at least one hardware device. The hardware device can be any kind of portable device that can be programmed. The device may also include, e.g., hardware like an Application-Specific Integrated Circuit (ASIC), or a combination of hardware and software like an ASIC and a Field-Programmable Gate Array (FPGA), or at least one microprocessor and at least one memory with software modules located therein. The method embodiments described herein could be implemented partly in hardware and partly in software. Alternatively, the embodiments may be implemented on different hardware devices, e.g., using a plurality of central processing units (CPUs).

As is traditional in the field of the inventive concepts, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the inventive concepts. Further, the blocks, units and/or modules of the example embodiments may be physically combined into more complex blocks, units and/or modules without departing from the scope of the inventive concepts.

The foregoing description of the embodiments will so fully reveal the nature of the embodiments herein that others can, by applying current knowledge, readily modify and/or adapt for various applications of such embodiments, and, therefore, such adaptations and modifications may be and are intended to be comprehended within the meaning and range of equivalents of the disclosed embodiments. It is to be understood that the phraseology or terminology employed herein is for the purpose of description and not of limitation. Therefore, while the embodiments herein have been described in terms of examples, those skilled in the art will recognize that the embodiments herein can be practiced with modification within the spirit and scope of the embodiments as described herein.

What is claimed is:

1. A D flip-flop comprising:
a master block configured to latch an input value of D at one of rising edge and a falling edge of a clock signal, based on the clock signal, the input value of D, and an inverted value of D; and
a slave block configured to propagate the input value of D at another one of the falling edge and the rising edge of the clock signal, based on the clock signal.

2. The D flip-flop as claimed in claim 1, wherein either one or each of the master block and the slave block comprises a pair of transistors configured to maintain opposite polarity between terminals within a respective one of the master block and the slave block.

3. The D flip-flop as claimed in claim 1, wherein the master block is further configured to propagate the input value of D to an input of the slave block, based on the clock signal being reset, and
wherein the slave block is further configured to propagate the input value of D to an output of the D flip-flop, based on the clock signal being set.

4. The D flip-flop as claimed in claim 1, wherein the master block and the slave block comprise first transistors in a Complementary Metal Oxide Semiconductor (CMOS) configuration and second transistors in a Transmission Gate (TG) configuration.

5. The D flip-flop as claimed in claim 1, wherein the master block is further configured to propagate the input value of D to an input of the slave block, based on the clock signal being reset to ‘0,’ and
wherein the slave block is further configured to propagate the input value of D to an output of the D flip-flop, based on the clock signal being set to ‘1.’

6. The D flip-flop as claimed in claim 1, wherein the master block comprises:
a first P-channel Metal Oxide Semiconductor (PMOS) transistor and a second PMOS transistor connected in series to a first voltage source VDD, wherein a gate of the first PMOS transistor is configured to receive the clock signal, and a gate of the second PMOS transistor is configured to receive the input value of D;
a first N-channel Metal Oxide Semiconductor (NMOS) transistor and a second NMOS transistor connected in series to a second voltage source VSS, wherein a gate of the first NMOS transistor is configured to receive the input value of D, and the first NMOS transistor is connected to the second PMOS transistor at a first node;
a third PMOS transistor and a fourth PMOS transistor connected in series to the first voltage source VDD, wherein a gate of the third PMOS transistor is configured to receive the clock signal, and a gate of the fourth PMOS transistor is configured to receive the inverted value of D; and
a third NMOS transistor and a fourth NMOS transistor connected in series to the second voltage source VSS, wherein a gate of the third NMOS transistor is configured to receive the inverted value of D, and the third NMOS transistor is connected to the fourth PMOS transistor at a second node,
wherein the second node is connected to a gate of the second NMOS transistor, and
wherein the first node is connected to a gate of the fourth NMOS transistor.

7. The D flip-flop as claimed in claim 6, wherein the slave block comprises:
a fifth PMOS transistor and a sixth PMOS transistor connected in series to the first voltage source VDD, wherein a gate of the sixth PMOS transistor is connected to the first node;
a fifth NMOS transistor and a sixth NMOS transistor connected in series to the second voltage source VSS, wherein a gate of the fifth NMOS transistor is configured to receive the clock signal, a gate of the sixth NMOS transistor is connected to the first node, and the fifth NMOS transistor is connected to the sixth PMOS transistor at a third node;
a seventh PMOS transistor and an eighth PMOS transistor connected in series to the first voltage source VDD, wherein a gate of the eighth PMOS transistor is connected to the second node; and
a seventh NMOS transistor and an eighth NMOS transistor connected in series to the second voltage source VSS, wherein a gate of the seventh NMOS transistor is configured to receive the clock signal, a gate of the eighth NMOS transistor is connected to the second node, and the seventh NMOS transistor is connected to the eighth PMOS transistor at a fourth node,
wherein the fourth node is connected to a gate of the fifth PMOS transistor, and
wherein the third node is connected to a gate of the seventh PMOS transistor.

8. A D flip-flop comprising:
a master block configured to latch an input value of D at one of a rising edge and a falling edge of a clock signal, based on an inverted version of the clock signal, the input value of D, and an inverted value of D; and
a slave block configured to propagate the input value of D at another one of the falling edge and the rising edge of the clock signal, based on the clock signal and the inverted version of the clock signal.

9. The D flip-flop as claimed in claim 8, wherein either one or each of the master block and the slave block comprises a pair of transistors configured to maintain opposite polarity between terminals within a respective one of the master block and the slave block.

10. The D flip-flop as claimed in claim 8, wherein the master block is further configured to propagate the input value of D to an input of the slave block, based on the clock signal being reset, and
wherein the slave block is further configured to propagate the input value of D to an output of the D flip-flop, based on the clock signal being set.

11. The D flip-flop as claimed in claim 8, wherein the master block and the slave block comprise first transistors in a Complementary Metal Oxide Semiconductor (CMOS) configuration and second transistors in a Transmission Gate (TG) configuration.

12. The D flip-flop as claimed in claim 8, wherein the master block is further configured to propagate the input value of D to an input of the slave block, based on the clock signal being reset to ‘0,’ and
wherein the slave block is further configured to propagate the input value of D to an output of the D flip-flop, based on the clock signal being set to ‘1.’

13. The D flip-flop as claimed in claim 8, wherein the master block comprises:
a first P-channel Metal Oxide Semiconductor (PMOS) transistor and a second PMOS transistor connected in series to a first voltage source VDD, wherein a gate of the second PMOS transistor is configured to receive the input value of D;
a first N-channel Metal Oxide Semiconductor (NMOS) transistor and a second NMOS transistor connected in series to a second voltage source VSS, wherein a gate of the first NMOS transistor is configured to receive the input value of D, a gate of the second NMOS transistor is configured to receive the inverted version of the clock signal, and the first NMOS transistor is connected to the second PMOS transistor at a first node;
a third PMOS transistor and a fourth PMOS transistor connected in series to the first voltage source VDD, wherein a gate of the third PMOS transistor is connected to the first node, and a gate of the fourth PMOS transistor is configured to receive the inverted value of D; and
a third NMOS transistor and a fourth NMOS transistor connected in series to the second voltage source VSS, wherein a gate of the third NMOS transistor is configured to receive the inverted value of D, a gate of the fourth NMOS transistor is configured to receive the inverted version of the clock signal, and the third NMOS transistor is connected to the fourth PMOS transistor at a second node, and
wherein the second node is connected to agate of the first PMOS transistor.

14. The D flip-flop as claimed in claim 13, wherein the slave block comprises:
a fifth PMOS transistor and a sixth PMOS transistor connected in series to the first voltage source VDD, wherein a gate of the fifth PMOS transistor is configured to receive the inverted version of the clock signal, and a gate of the sixth PMOS transistor is connected to the second node; and
a fifth NMOS transistor and a sixth NMOS transistor connected in series to the second voltage source VSS, wherein agate of the fifth NMOS transistor is connected to the second node, and a gate of the sixth NMOS transistor is configured to receive the clock signal.

15. A D flip-flop comprising:
a master block configured to latch an input value of D at one of a rising edge and a falling edge of a clock signal, based on an inverted version of the clock signal, the input value of D, and an inverted value of D; and
a slave block configured to propagate the input value of D at another one of the falling edge and the rising edge of the clock signal, based on the inverted version of the clock signal.

16. The D flip-flop as claimed in claim 15, wherein either one or each of the master block and the slave block comprises a pair of transistors configured to maintain opposite polarity between terminals within a respective one of the master block and the slave block.

17. The D flip-flop as claimed in claim 15, wherein the master block is further configured to propagate the input value of D to an input of the slave block, based on the clock signal being reset, and
wherein the slave block is further configured to propagate the input value of D to an output of the D flip-flop, based on the clock signal being set.

18. The D flip-flop as claimed in claim 15, wherein the master block and the slave block comprise first transistors in a Complementary Metal Oxide Semiconductor (CMOS) configuration and second transistors in a Transmission Gate (TG) configuration.

19. The D flip-flop as claimed in claim 15, wherein the master block is further configured to propagate the input value of D to an input of the slave block, based on the clock signal being reset to ‘0,’ and
wherein the slave block is further configured to propagate the input value of D to an output of the D flip-flop, based on the clock signal being set to ‘1.’

20. The D flip-flop as claimed in claim 15, wherein the master block comprises:
a first P-channel Metal Oxide Semiconductor (PMOS) transistor and a second PMOS transistor connected in series to a first voltage source VDD, wherein a gate of the second PMOS transistor is configured to receive the input value of D;
a first N-channel Metal Oxide Semiconductor (NMOS) transistor and a second NMOS transistor connected in series to a second voltage source VSS, wherein a gate of the first NMOS transistor is configured to receive the input value of D, a gate of the second NMOS transistor is configured to receive the inverted version of the clock signal, and the first NMOS transistor is connected to the second PMOS transistor at a first node;
a third PMOS transistor and a fourth PMOS transistor connected in series to the first voltage source VDD, wherein a gate of the third PMOS transistor is connected to the first node, and a gate of the fourth PMOS transistor is configured to receive the inverted value of D; and
a third NMOS transistor connected in series to the second NMOS transistor and the second voltage source VSS, wherein a gate of the third NMOS transistor is configured to receive the inverted value of D, and the third NMOS transistor is connected to the fourth PMOS transistor at a second node, and
wherein the second node is connected to a gate of the first PMOS transistor.
